(19) United States
(12) Patent Application Publication
(10) Pub. No.: US 2002/0095784 A1
(43) Pub. Date: Jul. 25, 2002

(54) Bumping process for chip scale packaging

(76) Inventor: Jen-Kuang Fang, Pingtung Hsien (TW)

Correspondence Address: J.C. Patents, Inc., 4 Venture, Suite 250, Irvine, CA, 92618, US

(21) Appl. No.: 09/815,804

(22) Filed: Mar. 23, 2001

(30) Foreign Application Priority Data
Jan. 20, 2001 (TW) 90101426

(51) Int. Cl. H05K 3/00; H01R 9/00

(52) U.S. Cl. 29/843

(57) ABSTRACT

A bumping process for chip scale packaging comprises: providing a chip, the chip having an active surface that has a plurality of bonding pads; sequentially forming an under bump metal (UBM) structure and a leaded bump thereon on each of the bonding pads, wherein the material of the leaded bumps is composed of tin and more than 85% of lead; forming a thermosetting plastic on the active surface that covers the leaded bumps; and grinding the surface of the thermosetting plastic to expose the leaded bumps.

### CROSS-REFERENCE TO RELATED APPLICATION

This application claims the priority benefit of Taiwan application serial no. 90101426, filed Jan. 20, 2001.

### BACKGROUND OF THE INVENTION

1. Field of the Invention

The invention relates to a bumping process for chip scale packaging. More particularly, the invention relates to a bumping process used in flip chip technology.

2. Description of the Related Art

Conventionally, chip scale package is defined as either a chip package which dimensions are less than 1.2 times the packaged chip dimensions, or a chip package in which the packaged chip area is at least 80% of the chip package area while the pitch of leads is less than 1 mm. Regardless the type of chip packaging structure, if only the chip packaging structure satisfies the foregoing criteria, then it can be regarded as of chip scale package type. To carry out chip scale packaging, a commonly use technology is that of “flip chip”.

Flip chip technology principally consists of forming conductive bumps on the chip I/O bonding pads, the chip is then flipped to be connected to a substrate through the conductive bumps. Such a type of connection structure should be distinguished from that of wire bonding, an advantage over wire bonding being various arrangements of I/O bonding pads, such as matrix arrangement or interlace arrangement, and providing the shortest distance between the chip and the substrate. Other advantages among which reduced surface area, high count of I/O bonding pads, a short signal transmission path and easy control of noise, are characteristic of flip chip packages.

At an intermediary stage of the flip chip process, after the chip being flipped, a reflow process takes the conductive bumps, formed on the chip, to a glass transition temperature to have the conductive bumps softened for connecting the chip to the substrate. Then, an underfill material fills the gap between the chip and the substrate, which completes the connection of the chip with the substrate. The underfill material is directed to protect the conductive bumps, after connection process, by sharing thermal stress caused by differential coefficient of thermal expansion between the chip and substrate.

Because the dimensions of the chip are substantially small while the I/O bonding pads count is high, the diameter of the conductive bumps being consequently substantially small, the gap between the chip and substrate is also substantially small. Practically, a method by capillarity is conventionally used to fill the underfill material. However, a capillarity process is very difficult to carry out without generating voids when the underfill material is filled, which may causes cracks during subsequent heating. Those and other drawbacks are better understood through the following description of a conventional bumping process, with the illustration of FIG. 1 through FIG. 4.

Referring now to FIG. 1 through FIG. 4, schematic cross-sectional views show a conventional bumping process. A wafer 100 has formed thereon a plurality of chips 102. Each of the chips has an active surface 102a on which are formed bonding pads 106. An under bump metal (UBM) structure 108 and a conductive bump 110 are sequentially formed on each of the bonding pads 106. Commonly, the formed conductive bumps 110 are composed of tin and lead which tin/lead ratio is 63:37, the glass transition temperature of such an alloy is approximately 183° C.

With reference to FIG. 2, a substrate 160 is prepared for being connected to the chip 102 by applying flux 164 on a plurality of contact pads 162 priory formed on the substrate 160. The conductive bumps 110 are aligned and put in contact with the contact pads 162. Then, a reflow process is performed at the glass transition temperature of approximately 183° C. to soften the conductive bumps 110 into bonded bumps 140, as shown in FIG. 3.

With reference to FIG. 4, then an underfill process by capillarity is performed to fill a thermosetting plastic 150 between the chip 102 and the substrate 160. The underfill process is performed at a temperature of 80° C., the temperature is then increased to 110° C. for solidification.

In addition to the great difficulty to perfectly carry out the underfill process as mentioned above, the speed of the underfill process by capillarity is moreover substantially limited. Moreover, the irregular shape of the conductive bumps, after achievement of reflow process, may render the underfill process even more difficult to be efficiently carried out. A solution for overcoming those problems is thus needed.

### SUMMARY OF THE INVENTION

One major aspect of the present invention is to provide a bumping process for chip scale packaging that can eliminate the need of an underfill process.

To attain the foregoing and other aspects, the present invention, according to a first preferred embodiment, proposes a bumping process for chip scale packaging comprising: providing a chip that has an active surface on which are formed a plurality of bonding pads; forming sequentially an under bump metal (UBM) structure and a leaded bump respectively on each of the bonding pads of the chip, wherein the under bump metal (UBM) structures are composed of tin and lead, the lead constituent being above 85%; forming a thermosetting plastic on the active surface of the chip to cover the leaded bumps; and grinding the surface of the thermosetting plastic to expose the leaded bumps.

By the above-described bumping process, the thermosetting plastic that is formed on the active surface of the chip and exposing the leaded bumps can substitute the conventional underfill process.

According to a second embodiment of the present invention, the thermosetting plastic on the active surface of the chip and exposing the leaded bumps can be formed through: forming a film on a top portion of the leaded bumps, the film separated from the active surface of the chip thus defining a gap; forming the thermosetting plastic filling between the film and active surface, according to either a molding method or dispensing method; and removing the film to expose the top portion of leaded bumps.

According to a third embodiment of the present invention, the thermosetting plastic on the active surface of the chip and exposing the leaded bumps can be formed through: grinding top portion of the leaded bumps to have a planarized top portion; and forming a thermosetting plastic on the active surface of the chip filling between the leaded bumps, such that the surface of the thermosetting plastic is coplanar with the planarized top portion of the leaded bumps that are exposed by.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 through FIG. 4 are schematic views illustrating various stages of the conventional bumping process for chip scale packaging;

FIG. 5 through FIG. 10 are schematic views illustrating various stages of a bumping process for chip scale packaging according to a first embodiment of the present invention;

FIG. 11 through FIG. 15 are schematic views illustrating various stages of a bumping process for chip scale packaging according to a second embodiment of the present invention; and

FIG. 16 through FIG. 19 are schematic views illustrating various stages of a bumping process for chip scale packaging according to a third embodiment of the present invention.

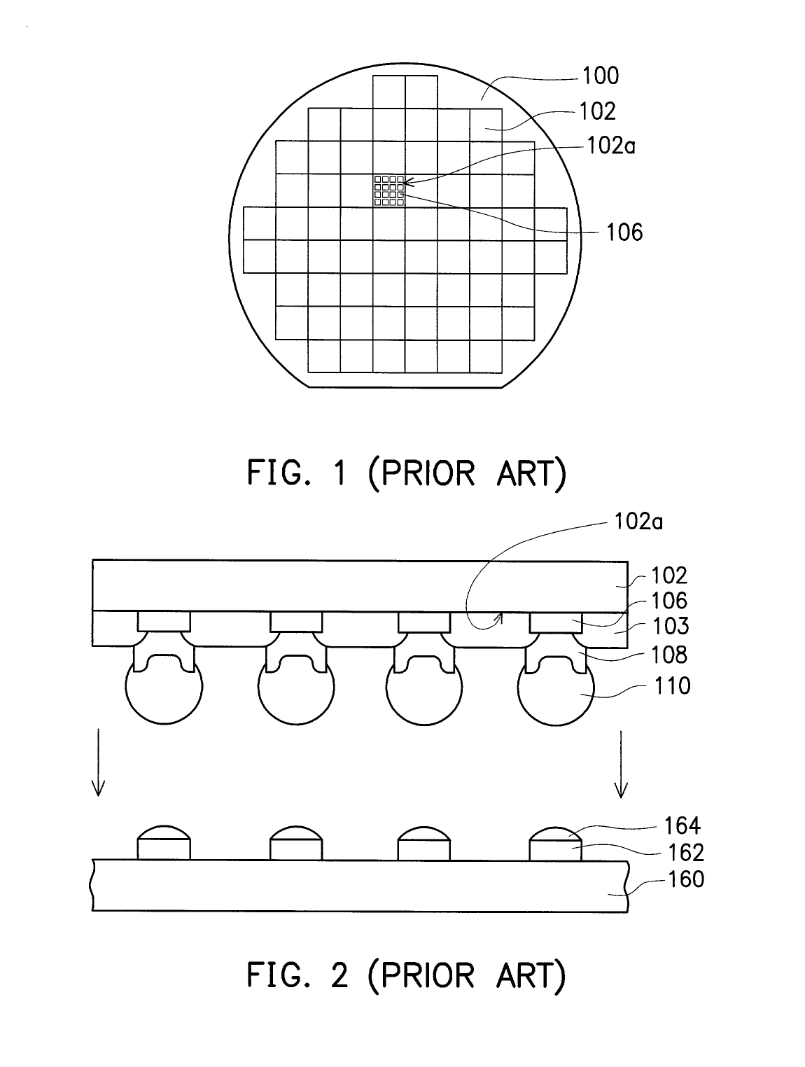

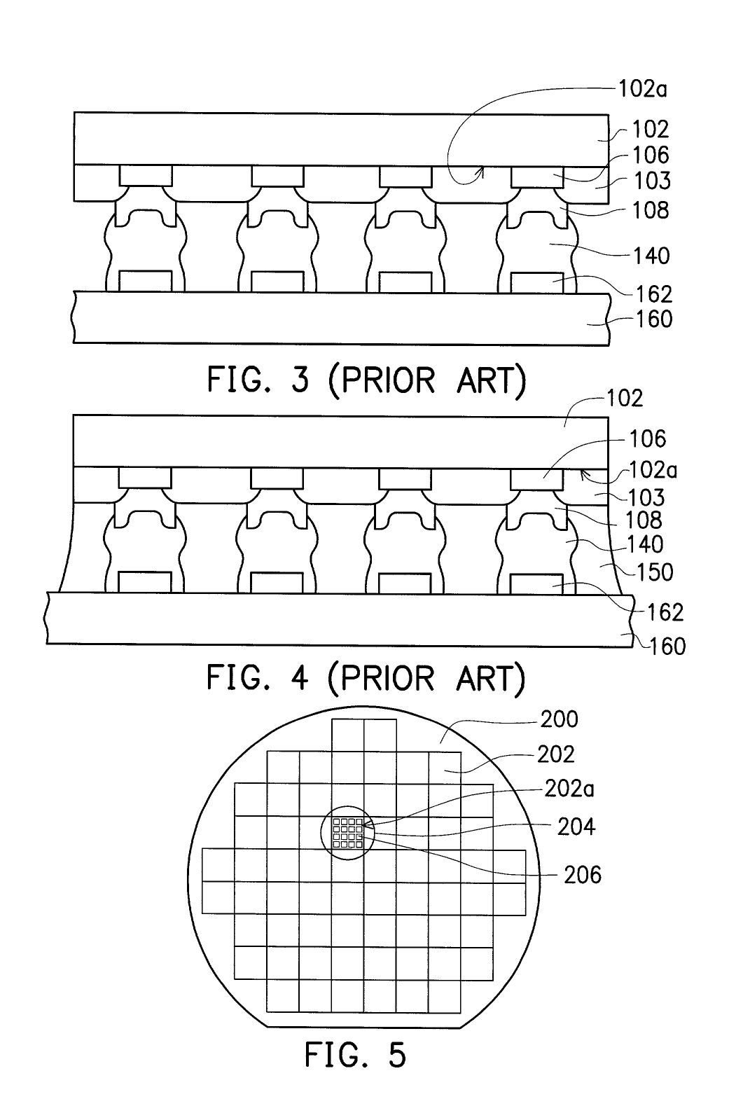

### DESCRIPTION OF THE PREFERRED EMBODIMENTS

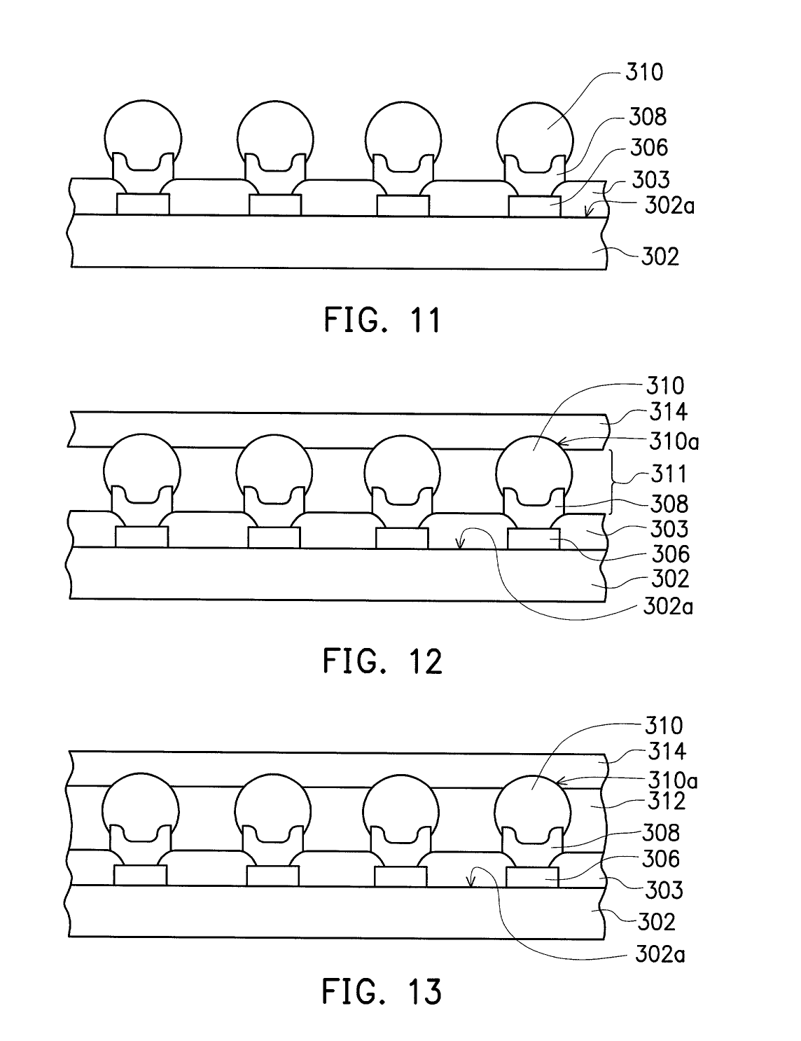

The following detailed description of the embodiments and examples of the present invention with reference to the accompanying drawings is only illustrative and not limiting. In the drawings, FIG. 5 through FIG. 10, FIG. 11 through FIG. 15, and FIG. 16 through FIG. 19 will be referred to for illustrating the detailed description of the bumping process according to respectively a first, second, and third embodiment of the present invention.

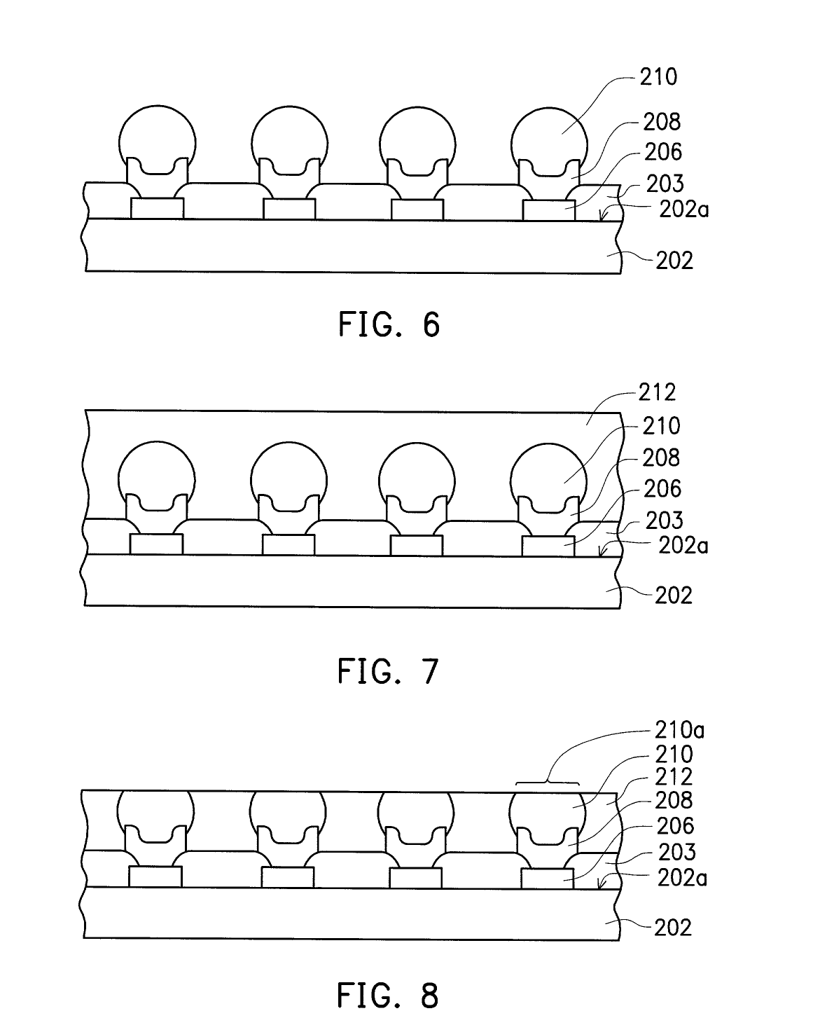

Referring now to FIG. 5 through FIG. 10, cross-sectional views schematically show a bumping process for chip scale packaging according to a first embodiment of the present invention. FIG. 5 is a schematically view showing a wafer having a plurality of chips 202 formed thereon, each of the chips 202 having a plurality of bonding pads 206. With reference to FIG. 6, an enlarged view of the zone 204 of FIG. 5 shows a an intermediary starting point in the bumping process for chip scale packaging according to a first embodiment of the present invention. Each of the chips 202 has an active surface 202a that has formed thereon, the bonding pads 206, and a passivation layer 203 that exposes the bonding pads 206. An under bump metal (UBM) structure 208 and a leaded bump 210 are sequentially formed on each of the bonding pads 206. The leaded bumps 210 are composed of tin and lead, wherein the lead constituent is higher than 85%. Preferably, tin/lead ratio is 3:97, 5:95, or 10:90. The under bump metal (UBM) structure 208 is composed of chromium, titanium, titanium-tungsten alloys, copper, or other alloys of chromium, titanium, tungsten and copper.

With reference to FIG. 7, a thermosetting plastic 212 is formed on the active surface 202a, and covering the leaded bumps 210. Using a thermosetting plastic material is advantageous because it is commercially easily available and offers relatively high temperature stability and relatively low coefficient of thermal expansion properties. The thermosetting plastic 212 can be formed, for instance, according to either a molding method or dispensing method. With reference to FIG. 8, the surface of the thermosetting plastic 212 is ground until planarized top portion 210a of the leaded bumps 210, exposed by the thermosetting plastic 212, is obtained. After the bumping process is thence completed, the wafer 200 is diced to singularize each of the chips 202 (not shown).

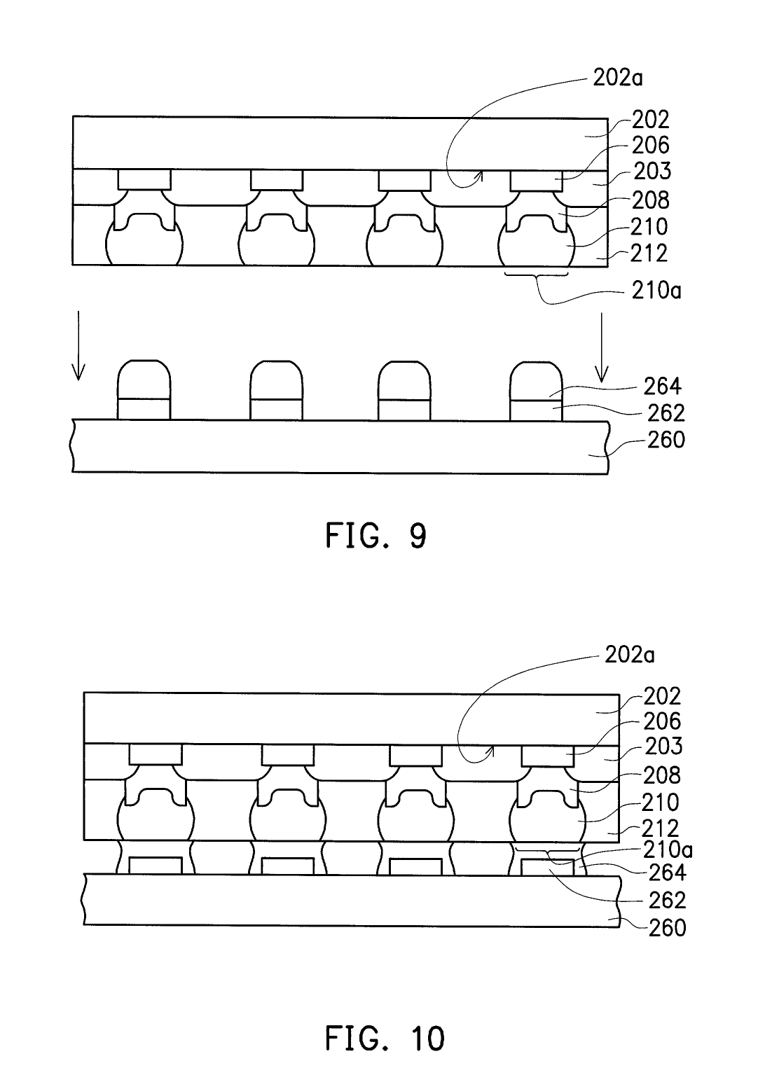

With reference to FIG. 9 and FIG. 10, cross-sectional views schematically show a chip connection process in the chip scale packaging, according to the first embodiment of the present invention. A surface of a carrier 260 has a plurality of contact pads 262 formed thereon. A solder paste 264 is applied on each of the contact pads 262. The solder paste 264 is composed of tin and lead, wherein the lead constituent is lower than that of the leaded bumps 210. Each of the singularized chips 202 is flipped and arranged above the carrier 260 such that the leaded bumps 210 are respectively aligned with the contact pads 262.

With reference to FIG. 10, after the leaded bumps 210 of the chip 202 are respectively aligned and in contact with the contact pads 262 of the carrier 260, a reflow process is then performed, by taking the solder paste 264 to a glass transition temperature. Thence, the solder paste 264 is softened. Because the lead constituent of the leaded bumps 210 is higher than the lead constituent of the solder paste 264, the glass transition temperature of the leaded bumps 210 is consequently higher than that of the solder paste 264. As a result, when the solder paste 264 is softened, the leaded bumps 210 are not. The connection of the chip 202 with the carrier 260 can thus be effectively achieved without the bump shape deformation occurring in a conventional technique.

Referring now to FIG. 11 through FIG. 15, cross-sectional views schematically show a bumping process for chip scale packaging according to a second embodiment of the present invention. With reference to FIG. 11, a passivation layer 303, formed on an active surface 302a of a chip 302, exposes a plurality of bonding pads 306. An under bump metal (UBM) structure 308 and a leaded bump 310 are sequentially formed on each of the bonding pads 306. The leaded bumps 310 are composed of tin and lead, wherein the lead constituent is higher than 85%. Preferably, tin/lead ratio is 3:97, 5:95, or 10:90. The under bump metal (UBM) structure 308 is composed of chromium, titanium, titanium-tungsten alloys, copper, or other alloys of chromium, titanium, tungsten and copper.

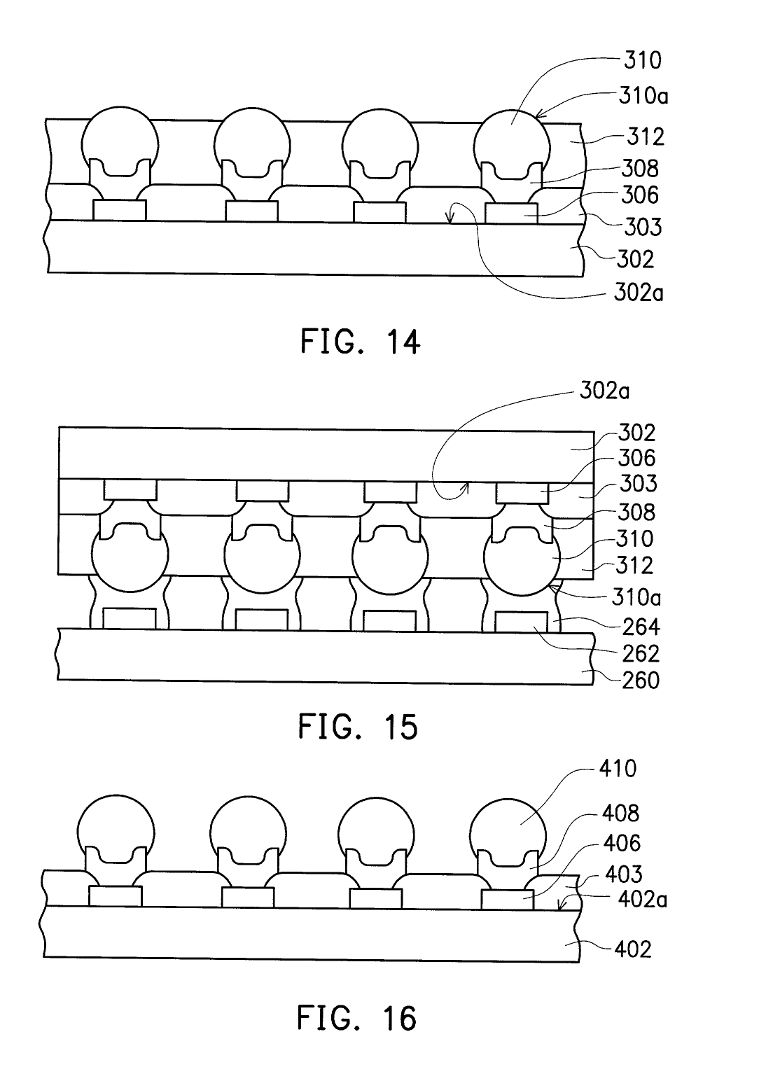

With reference to FIG. 12, a film 314 is formed on the leaded bumps 310 to cover top portion 310a thereof, wherein the film 314 is separated from the passivation layer 303, on the active surface 302a, by a gap 311. With reference to FIG. 13, a thermosetting plastic 312, formed on the active surface 302a, fills the gap 311 between the film 314 and the active surface 302a. The thermosetting plastic 312 can be formed, for instance, according to either a molding method or dispensing method. With reference to FIG. 14, the film 314 is then removed exposing the top portion 310a of the leaded bumps 310.

With reference to FIG. 15, a cross-sectional view schematically shows a chip connection process in the chip scale packaging, according to the second embodiment of the present invention. Reference numerals that are similar to reference numerals used in the description of the first embodiment refer to like elements, their description is thus omitted hereafter. After the bumping process and singulation process are achieved, each of the chips 302 is flipped and arranged above the carrier 260, such that the leaded bumps 310 of the chip 302 are respectively aligned and in contact with the contact pads 262 of the carrier 260. A reflow process is then performed to soften the solder paste 264, and achieve the connection of the chip 302 with the carrier 260.

Referring now to FIG. 16 through FIG. 19, cross-sectionals schematically show a bumping process for chip scale packaging according to a third embodiment of the present invention. With reference to FIG. 16, a passivation layer 403, formed on an active surface 402a of a chip 402, exposes a plurality of bonding pads 406. An under bump metal (UBM) structure 408 and a leaded bump 410 are sequentially formed on each of the bonding pads 406. The leaded bumps 410 are composed of tin and lead, wherein the lead constituent is higher than 85%. Preferably, tin/lead ratio is 3:97, 5:95, or 10:90. The under bump metal (UBM) structure 408 is composed of chromium, titanium, titanium-tungsten alloys, copper, or other alloys of chromium, titanium, tungsten and copper.

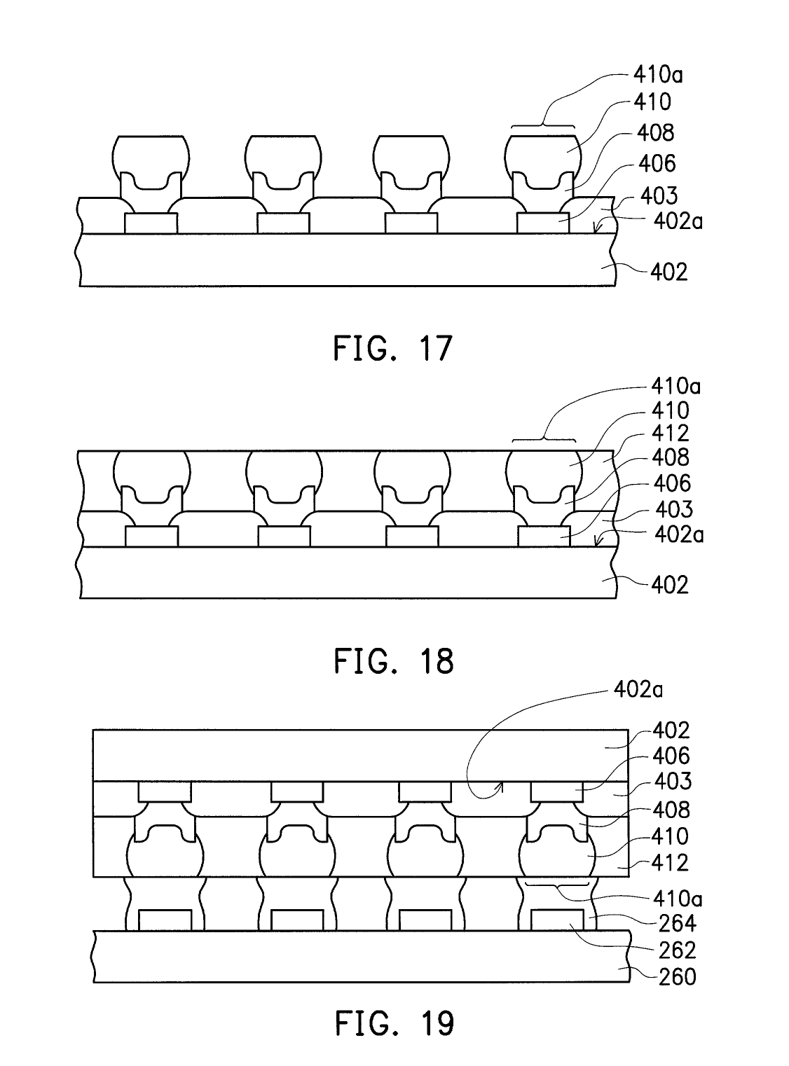

With reference to FIG. 17, the leaded bumps 410 are ground to have planarized top portion 410a thereof. A thermosetting plastic 412 is then formed on the active surface 402a and fills between the leaded bumps 410. The thermosetting plastic 412 is such that its surface is coplanar with the planarized top portion 410a of the leaded bumps 410 that are exposed by. The thermosetting plastic 412 can be formed, for instance, according to a molding method. The wafer is then diced to singularize the chips 402.

With reference to FIG. 19, a cross-sectional view schematically shows a chip connection process in the chip scale packaging, according to the third embodiment of the present invention. Reference numerals that are identical to reference numerals used in the description of the first embodiment refer to same elements, their description is thus omitted hereafter. After the bumping process and singulation process are achieved, each of the chips 402 is flipped and arranged above the carrier 260, such that the leaded bumps 410 of the chip 402 are respectively aligned and in contact with the contact pads 262 of the carrier 260. A reflow process is then performed to soften the solder paste 264, and achieve the connection of the chip 402 with the carrier 260.

In summary, the foregoing description of embodiments and examples of the present invention reveals at least the following features and advantages. Since the thermosetting plastic is formed, according to the embodiments and examples of the present invention, by not being filled directly between the chip and the carrier as in the conventional underfill process, related high degree of difficulty in workability can thus be overcome, and production throughput can be increased.

Furthermore, using leaded bumps that are connected to solder paste which lead constituent is relatively lower than that of the leaded bumps allows to have different glass transition temperature of the both. As a result, during reflow process, the leaded bumps are not deformed while the solder paste is softened, which enables an effective and reliable connection of the chip with the carrier.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A bumping process for chip scale packaging comprising:
providing a chip that has an active surface, the active surface having a plurality of bonding pads;
forming a passivation layer on the active surface of the chip exposing the bonding pads thereof;
forming an under bump metal (UBM) structure on each of the bonding pads;
forming a plurality of leaded bumps respectively on the under bump metal (UBM) structures, wherein the material of the leaded bumps is composed of tin and lead, and the lead constituent is above 85%;
forming a thermosetting plastic on the active surface of the chip that covers the leaded bumps; and
grinding the surface of the thermosetting plastic to expose the leaded bumps.

2. The bumping process of claim 1, wherein the tin/lead ratio of the leaded bumps is 3:97, 5:95, or 10:90.

3. The bumping process of claim 1, wherein the material of the under bump metals (UBM) is chromium, titanium, titanium-tungsten alloy, copper, or any alloys of chromium, titanium, tungsten and copper.

4. The bumping process of claim 1, wherein the thermosetting plastic is formed by molding.

5. The bumping process of claim 1, wherein the thermosetting plastic is formed by dispensing.

6. The bumping process of claim 1, wherein the chip is further capable of being mounted on a carrier having a plurality of contact pads formed thereon, wherein the contact pads has respectively thereon a solder paste that is directed to connect the contact pads to the leaded bumps, the solder paste being composed of tin and lead, wherein the lead constituent of the solder paste is lower than the lead constituent of the leaded bumps.

7. A bumping process for chip scale packaging comprising:
providing a chip that has an active surface, the active surface having a plurality of bonding pads;
forming a passivation layer on the active surface of the chip exposing the bonding pads thereof;
forming an under bump metal (UBM) structure on each of the bonding pads;
forming a plurality of leaded bumps respectively on the under bump metal (UBM) structures, wherein the material of the leaded bumps is composed of tin and lead, and the lead constituent is above 85%, each of the leaded bumps having a top portion opposite to the under bump metal onto which the leaded bump is formed;
forming a film that covers the top portion of the leaded bumps, wherein the film is separated from the active surface of the chip by a gap;
forming a thermosetting plastic on the active surface of the chip, wherein the thermosetting plastic fills the gaps between the active surface of the chip and the film; and
removing the film to expose the top portion of the leaded bumps.

8. The bumping process of claim 7, wherein the tin/lead ratio of the leaded bumps are 3:97, 5:95, or 10:90.

9. The bumping process of claim 7, wherein the material of the under bump metals (UBM) is chromium, titanium, titanium-tungsten alloy, copper, or any alloys of chromium, titanium, tungsten and copper.

10. The bumping process of claim 7, wherein the thermosetting plastic is formed by molding.

11. The bumping process of claim 7, wherein the thermosetting plastic is formed by dispensing.

12. The bumping process of claim 7, wherein the chip is further capable of being mounted on a carrier having a plurality of contact pads formed thereon, wherein the contact pads has respectively thereon a solder paste that is directed to connect the contact pads to the leaded bumps, the solder paste being composed of tin and lead, wherein the lead constituent of the solder paste is lower than the lead constituent of the leaded bumps.

13. A bumping process for chip scale packaging comprising:
providing a chip that has an active surface, the active surface having a plurality of bonding pads;
forming a passivation layer on the active surface of the chip exposing the bonding pads thereof;
forming an under bump metal (UBM) structure on each of the bonding pads;
forming a plurality of leaded bumps respectively on the under bump metal (UBM) structures, wherein the material of the leaded bumps is composed of tin and lead, and the lead constituent is above 85%, each of the leaded bumps having a top portion opposite to the under bump metal onto which the leaded bump is formed;
grinding the top portion of the leaded bumps to obtain a planar top portion; and
forming a thermosetting plastic on the active surface that fills between the leaded bumps, wherein the surface of the thermosetting plastic is coplanar with the planarized top portion of the leaded bumps that are externally exposed.

14. The bumping process of claim 13, wherein the tin/lead ratio of the leaded bumps comprises 3:97, 5:95, or 10:90.

15. The bumping process of claim 13, wherein the material of the under bump metals (UBM) is chromium, titanium, titanium-tungsten alloy, copper, or any alloys of chromium, titanium, tungsten and copper.

16. The bumping process of claim 13, wherein the thermosetting plastic is formed by molding.

17. The bumping process of claim 13, wherein the chip is further capable of being mounted on a carrier having a plurality of contact pads formed thereon, wherein the contact pads has respectively thereon a solder paste that is directed to connect the contact pads to the leaded bumps, the solder paste being composed of tin and lead, wherein the lead constituent of the solder paste is lower than the lead constituent of the leaded bumps.
